(19) United States
(12) Patent Application Publication
(10) Pub. No.: US 2014/0352604 A1
(43) Pub. Date: Dec. 4, 2014

(54) METHOD FOR GROWING ß-Ga2O3 SINGLE CRYSTAL

(71) Applicants: TAMURA CORPORATION, Tokyo (JP); KOHA CO., LTD., Tokyo (JP)

(72) Inventors: Kimiyoshi Koshi, Tokyo (JP); Haruka Matsubara, Tokyo (JP); Shinya Watanabe, Tokyo (JP)

(21) Appl. No.: 14/358,011

(22) PCT Filed: Nov. 12, 2012
(86) PCT No.: PCT/JP2012/079265

§ 371 Date: May 13, 2014

(30) Foreign Application Priority Data
Nov. 15, 2011 (JP) 2011-249891

(51) Int. Cl. C30B 15/34; C30B 29/16; C30B 15/36

(52) U.S. Cl. CPC C30B 15/34; C30B 15/36; C30B 29/16
USPC 117/26

(57) ABSTRACT

A method for growing a β-Ga₂O₃ single crystal, which is capable of effectively suppressing twinning of the using an Edge-defined film-fed growth (EFG) method, includes: a seed crystal brought into contact with a Ga₂O₃ melt; and the seed crystal is pulled and a β-Ga₂O₃ single crystal is grown without performing a necking process. In the method for growing a β-Ga₂O₃ single crystal, the widths of the β-Ga₂O₃ single crystal are 110% or less of the widths of the seed crystal in all directions.

### TECHNICAL FIELD

The invention relates to a method for growing a β-Ga₂O₃ based single crystal and, in particular, to a method for growing a β-Ga₂O₃ based single crystal which is capable of effectively controlling the twinning of crystal.

### BACKGROUND ART

A crystal growth method is known in which an InP single crystal having substantially the same size as a seed crystal is grown by the Bridgman method (see, e.g. NPL 1). According to the method disclosed in NPL 1, it is possible to obtain an InP single crystal without twins.

### CITATION LIST

### Non Patent Literature

[NPL 1]

F. Matsumoto et al., Journal of Crystal Growth, 132 (1993), pp. 348-350

### SUMMARY OF INVENTION

### Technical Problem

However, in growing a single crystal by the Bridgman method, it is necessary to remove the single crystal from a crucible after the crystal growth. If the crucible is formed of a material having a high adhesion to the crystal, it is difficult to remove the grown single crystal therefrom.

In case of growing a Ga₂O₃ crystal, a crucible formed of Ir is generally used but Ir has a high adhesion to a β-Ga₂O₃ based single crystal. Therefore, it is difficult to remove the single crystal from the crucible when the β-Ga₂O₃ based single crystal is grown by the Bridgman method.

It is an object of the invention to provide a method for growing a β-Ga₂O₃ based single crystal that allows the β-Ga₂O₃ based single crystal to be obtained while controlling the twinning of crystal.

### Solution to Problem

According to one embodiment of the invention, a method for growing a β-Ga₂O₃ based single crystal as defined in [1] to [4] below is provided so as to achieve the above object.

[1] A method for growing a β-Ga₂O₃ based single crystal using an EFG method, comprising:
a step of bringing a seed crystal into contact with a Ga₂O₃ based melt; and
a step of pulling the seed crystal to grow a β-Ga₂O₃ based single crystal without conducting a necking process,
wherein a width of the β-Ga₂O₃ based single crystal is not more than 110% of a width of the crystal seed in all directions.

[2] The method for growing a β-Ga₂O₃ based single crystal according to [1], wherein the width of the β-Ga₂O₃ based single crystal is not more than 100% of the width of the crystal seed in all directions.

[3] The method for growing a β-Ga₂O₃ based single crystal according to [2], wherein the width of the β-Ga₂O₃ based single crystal is equal to the width of the crystal seed in all directions.

[4] The method for growing a β-Ga₂O₃ based single crystal according to any one of [1] to [3], wherein the β-Ga₂O₃ based single crystal is grown in a b-axis direction thereof.

### Advantageous Effects of Invention

According to one embodiment of the invention, a method for growing β-Ga₂O₃ based single crystal can be provided that allows the β-Ga₂O₃ based single crystal to be obtained while controlling the twinning of crystal.

### BRIEF DESCRIPTION OF DRAWINGS

[FIG. 1]

FIG. 1 is a vertical cross sectional view showing a part of an EFG crystal manufacturing apparatus in an embodiment.

[FIG. 2]

FIG. 2 is a perspective view showing a state during growth of a β-Ga₂O₃ based single crystal.

[FIG. 3A]

FIG. 3A is a partially enlarged view showing the vicinity of a boundary between a seed crystal (width: W₁) and a β-Ga₂O₃ based single crystal (width: W₂) in the embodiment (in case of W₁=W₂).

[FIG. 3B]

FIG. 3B is a partially enlarged view showing the vicinity of a boundary between a seed crystal (width: W₁) and a β-Ga₂O₃ based single crystal (width: W₂) in the embodiment (in case of W₁>W₂).

[FIG. 3C]

FIG. 3C is a partially enlarged view showing the vicinity of a boundary between a seed crystal (width: W₁) and a β-Ga₂O₃ based single crystal (width: W₂) in the embodiment (in case of W₁<W₂).

[FIG. 4]

FIG. 4 is a partially enlarged view showing a crystal seed having a neck portion in the vicinity of the boundary and a β-Ga₂O₃ based single crystal in Comparative Example.

### DESCRIPTION OF EMBODIMENTS

In the present embodiment, a β-Ga₂O₃ based single crystal is grown by the EFG (Edge-defined film-fed growth) method without performing a necking process or a process of greatly broadening a shoulder.

The necking process is a process to form a thin neck portion at the time of bringing a seed crystal into contact with a melt of crystal raw material. After forming the neck portion, a crystal is grown while increasing a width to the desired size (a shoulder broadening process) and the crystal is then grown while keeping the desired width.

Dislocations in the seed crystal can be prevented from being passed to a grown crystal by performing the necking process. However, when the necking process is performed during growing a β-Ga₂O₃ based single crystal, the twin is likely to be formed in the process of greatly broadening a shoulder after the necking process.

It is possible to control the twinning of crystal by rapidly cooling the β-Ga₂O₃ based single crystal after the necking process by e.g. a method of increasing a pulling speed of the crystal. However, a crack may be generated in the β-Ga₂O₃ based single crystal due to the thermal shock.

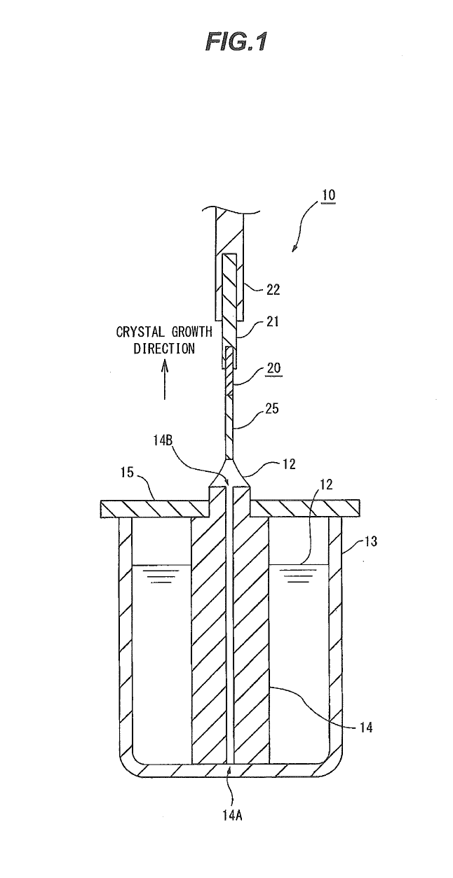

FIG. 1 is a vertical cross sectional view showing a part of an EFG crystal manufacturing apparatus in the embodiment. This EFG crystal manufacturing apparatus 10 has a crucible 13 containing a Ga₂O₃ based melt 12, a die 14 placed in the crucible 13 and having a slit 14A, a lid 15 covering the upper surface of the crucible 13 except an opening 14B of the slit 14A, a crystal seed holder 21 for holding a β-Ga₂O₃ based seed crystal (hereinafter, referred as “seed crystal”) 20 and a shaft 22 vertically movably supporting the crystal seed holder 21.

The crucible 13 contains the Ga₂O₃ based melt 12 which is obtained by melting β-Ga₂O₃ based powder. The crucible 13 is formed of a metal material having sufficient heat resistance to contain the Ga₂O₃ based melt 12, such as iridium.

The die 14 has the slit 14A to draw up the Ga₂O₃ based melt 12 by capillary action.

The lid 15 prevents the high-temperature Ga₂O₃ based melt 12 from evaporating from the crucible 13 and further prevents the vapor of the Ga₂O₃ based melt 12 from attaching to a portion other than the upper surface of the slit 14A.

The seed crystal 20 is moved down and is brought into contact with the Ga₂O₃ based melt 12 which is drawn up by capillary action. Then, the seed crystal 20 in contact with the Ga₂O₃ based melt 12 is pulled up, thereby growing a plate-like β-Ga₂O₃ based single crystal 25. The crystal orientation of the β-Ga₂O₃ based single crystal 25 is the same as the crystal orientation of the seed crystal 20 and, for example, a plane orientation and an angle in a horizontal plane of the bottom surface of the seed crystal 20 are adjusted to control the crystal orientation of the β-Ga₂O₃ based single crystal 25.

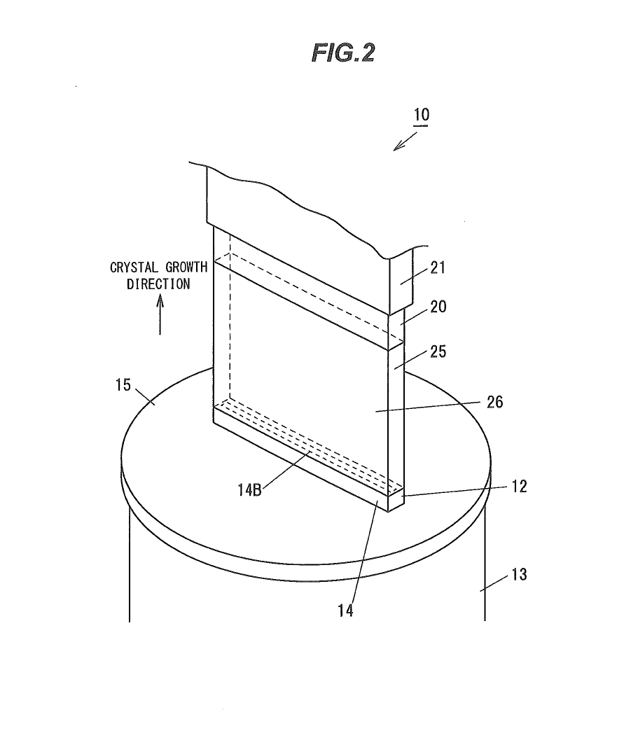

FIG. 2 is a perspective view showing a state during growth of a β-Ga₂O₃ based single crystal. A surface 26 in FIG. 2 is a principal surface of the β-Ga₂O₃ based single crystal 25 which is parallel to a slit direction of the slit 14A. When a β-Ga₂O₃ based substrate is formed by cutting out from the grow β-Ga₂O₃ based single crystal 25, the plane orientation of the surface 26 of the β-Ga₂O₃ based single crystal 25 is made to coincide with the desired plane orientation of the principal surface of the β-Ga₂O₃ based substrate. When forming a β-Ga₂O₃ based substrate of which principal surface is e.g., a (101) plane, the plane orientation of the surface 26 is (101). The grown β-Ga₂O₃ based single crystal 25 also can be used as a seed crystal for growing a new β-Ga₂O₃ based single crystal.

The β-Ga₂O₃ based single crystal 25 and the seed crystal 20 are β-Ga₂O₃ single crystals, or are β-Ga₂O₃ single crystals with an element such as Cu, Ag, Zn, Cd, Al, In, Si, Ge or Sn added thereto. The β-Ga₂O₃ crystal has a β-gallia structure belonging to the monoclinic system and typically has lattice constants of a₀=12.23 Å, b₀=3.04 Å, c₀=5.80 Å, α=γ=90° and β=103.8°.

A twin crystal formed during growth of the β-Ga₂O₃ based single crystal is composed of two mirror-symmetrical β-Ga₂O₃ based crystals. The planes of symmetry of the β-Ga₂O₃ based crystal twin (twin planes) are (100) planes. When the β-Ga₂O₃ based single crystal is grown by the EFG method, the twin is likely to be formed in the process of greatly broadening a shoulder after the necking process.

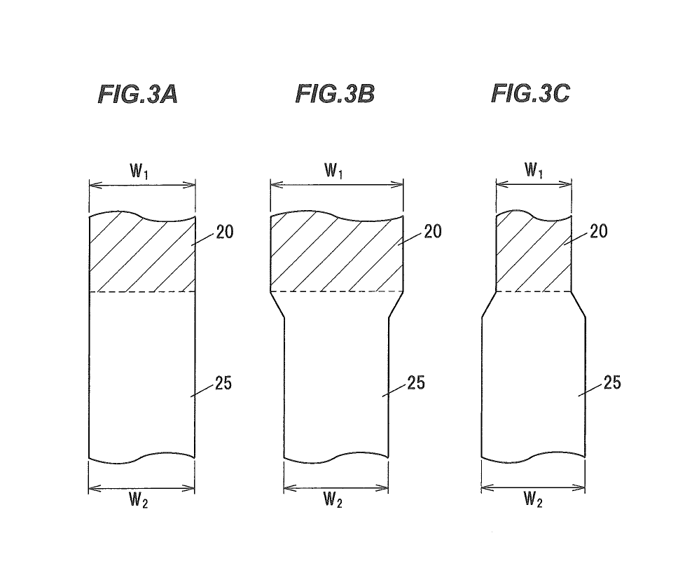

FIGS. 3A to 3C are partially enlarged views showing the vicinity of a boundary between a seed crystal and a β-Ga₂O₃ based single crystal in the present embodiment. W₁=W₂ in FIG. 3A, W₁>W₂ in FIG. 3B and W₁<W₂ in FIG. 3C where W₁ and W₂ are respectively the width of the seed crystal 20 and that of the β-Ga₂O₃ based single crystal 25.

In any of FIGS. 3A to 3C, a neck portion formed by the necking process is not present in the vicinity of the boundary between the seed crystal 20 and the β-Ga₂O₃ based single crystal 25. Therefore, the β-Ga₂O₃ based single crystal 25 does not contain twins or only contains a trace amount of twins. Note that, there is a tendency that crystal twinning proceeds with an increase in a ratio of W₂ to W₁ even in the case that the necking process is not performed. Therefore, W₂ is required to be not more than 110% of W₁.

In addition, the above-mentioned relation between W₂ and W₁ is true for the widths of the seed crystal 20 and the β-Ga₂O₃ based single crystal 25 in all directions. In other words, in the present embodiment, the width of the β-Ga₂O₃ based single crystal 25 is not more than 110% of the width of the seed crystal 20 in all directions.

Furthermore, in order to control the twinning of crystal in the β-Ga₂O₃ based single crystal 25 more effectively, the width of the β-Ga₂O₃ based single crystal 25 is preferably not more than 100% of the width of the seed crystal 20 in all directions. More preferably, the width of the β-Ga₂O₃ based single crystal 25 is equal to the width of the seed crystal 20 in all directions.

The width W₂ of the β-Ga₂O₃ based single crystal 25 with respect to the width W₁ of the seed crystal 20 can be controlled by, e.g., a temperature condition during growth of the β-Ga₂O₃ based single crystal 25. In this case, the lower the temperature during growth of the β-Ga₂O₃ based single crystal 25, the greater the width W₂.

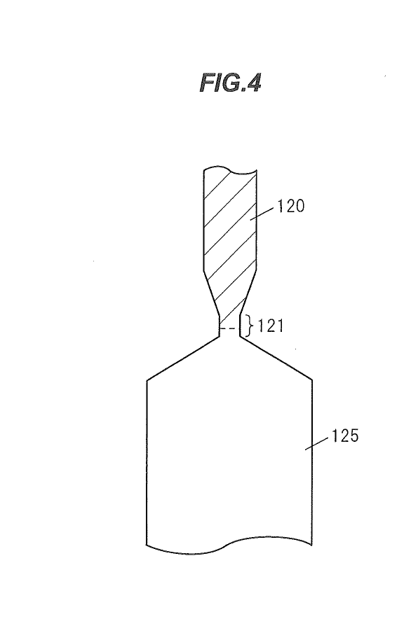

FIG. 4 is a partially enlarged view showing a crystal seed having a neck portion in the vicinity of the boundary and a β-Ga₂O₃ based single crystal in Comparative Example. A neck portion 121 is present in the vicinity of the boundary between a seed crystal 120 and a β-Ga₂O₃ based single crystal 125. The β-Ga₂O₃ based single crystal 125 is formed through the process of greatly broadening a shoulder after the necking process and thus often contains many twins.

When the β-Ga₂O₃ based single crystal 125 is grown in, e.g., the b-axis direction, the average number of twins on the principal surface (a surface parallel to the page surface) per 1 cm in a direction perpendicular to the b-axis is 30.7 to 37.0.

On the other hand, in the present embodiment, it is possible to form the β-Ga₂O₃ based single crystal 25 in which the average number of twins on the surface 26 per 1 cm in a direction perpendicular to the b-axis is substantially zero even when the β-Ga₂O₃ based single crystal 25 is grown in the b-axis direction.

An example of a growth condition of the β-Ga₂O₃ based single crystal 25 in the present embodiment will be described below.

The β-Ga₂O₃ based single crystal 25 is grown in, e.g., a nitrogen atmosphere.

The seed crystal 20 is substantially the same size or larger than the β-Ga₂O₃ based single crystal 25 and is thus larger than a crystal seed used for typical crystal growth and is fragile to thermal shock. Therefore, a height of the seed crystal 20 from the die 14 before contact with the Ga₂O₃ based melt 12 is preferably low to some extent and is, e.g., 10 mm. In addition, a descending speed of the seed crystal 20 until the contact with the Ga₂O₃ based melt 12 is preferably low to some extent and is, e.g., 1 min/min.

Standby time until pulling up the seed crystal 20 after the contact with the Ga₂O₃ based melt 12 is preferably long to some extent in order to further stabilize the temperature to prevent thermal shock, and is, e.g., 10 min.

A temperature rise rate at the time of melting a raw material in the crucible 13 is low to some extent in order to prevent a rapid increase in temperature around the crucible 13 and resulting thermal shock on the seed crystal 20, and the raw material is melted over, e.g., 11 hours.

### EFFECTS OF THE EMBODIMENT

In the present embodiment, the Ga₂O₃ based single crystal is grown without performing the necking or the process of greatly broadening a shoulder, which can effectively control the twinning of crystal in the β-Ga₂O₃ based single crystal.

In general, in case of growing β-Ga₂O₃ based single crystal by the EFG method, the crystal is likely to be twinned especially when the crystal is grown in the b-axis direction thereof. However, in the present embodiment, it is possible to control the twinning of crystal even if the β-Ga₂O₃ based single crystal is grown in the b-axis direction.

Although the embodiment of the invention has been described above, the invention according to claims is not to be limited to the above-mentioned embodiment. Further, please note that all combinations of the features described in the embodiment are not necessary to solve the problem of the invention.

### INDUSTRIAL APPLICABILITY

It is possible to provide a method for growing a β-Ga₂O₃ based single crystal which is capable of effectively controlling the twinning of crystal.

### REFERENCE SIGNS LIST

10 EFG crystal manufacturing apparatus
20 crystal seed
25 β-Ga₂O₃ based single crystal

1. A method for growing a β-Ga₂O₃ based single crystal using an Edge-defined film-fed growth (EFG) method, comprising:
bringing a seed crystal into contact with a Ga₂O₃ based melt; and
pulling the seed crystal to grow a β-Ga₂O₃ based single crystal without conducting a necking process,
wherein a width of the β-Ga₂O₃ based single crystal is not more than 110% of a width of the crystal seed in all directions.

2. The method for growing a β-Ga₂O₃ based single crystal according to claim 1, wherein the width of the β-Ga₂O₃ based single crystal is not more than 100% of the width of the crystal seed in all directions.

3. The method for growing a β-Ga₂O₃ based single crystal according to claim 2, wherein the width of the β-Ga₂O₃ based single crystal is equal to the width of the crystal seed in all directions.

4. The method for growing a β-Ga₂O₃ based single crystal according to claim 1, wherein the β-Ga₂O₃ based single crystal is grown in a b-axis direction thereof.

5. The method for growing a β-Ga₂O₃ based single crystal according to claim 2, wherein the β-Ga₂O₃ based single crystal is grown in a b-axis direction thereof.

6. The method for growing a β-Ga₂O₃ based single crystal according to claim 3, wherein the β-Ga₂O₃ based single crystal is grown in a b-axis direction thereof.
